(19) United States
(12) Patent Application Publication
(10) Pub. No.: US 2026/0299657 A1
(43) Pub. Date: Oct. 1, 2026

(54) VERTICAL POWER SUPPLY ASSEMBLY AND SMART CARD ASSEMBLY WITH INTEGRATED HEAT SINK

(71) Applicant: MetaPWR Electronics Co., Ltd., Shanghai (CN)

(72) Inventors: Jianhong ZENG, Shanghai (CN); Shouyu HONG, Shanghai (CN)

(73) Assignee: MetaPWR Electronics Co., Ltd., Shanghai (CN)

(21) Appl. No.: 19/574,431

(22) Filed: Mar. 23, 2026

(30) Foreign Application Priority Data
Mar. 27, 2025 (CN) 202510375140.5

(51) Int. Cl. G06F 1/20; G06F 1/188; H05K 7/20

(52) U.S. Cl. CPC G06F 1/206; G06F 1/188; H05K 7/20336; H05K 7/20381; H05K 7/20509

(57) ABSTRACT

A vertical power supply assembly includes multiple vertical power supply modules and a vertical heat dissipation device. In scenarios where vertical power supply is implemented, the heat dissipation of the vertical power supply modules is achieved through the vertical heat dissipation device. The present application further provides a smart card assembly including a smart card mainboard, an XPU chip, an XPU substrate, the vertical power supply modules, a main heat dissipation device, and the vertical heat dissipation device; the vertical heat dissipation device and the main heat dissipation device are connected to rapidly and effectively dissipate heat from a bottom surface of the smart card mainboard.

### CROSS-REFERENCE TO RELATED APPLICATIONS

This application claims the priority benefit of Chinese patent application no. 202510375140.5 filed on Mar. 27, 2025. The entirety of the above-mentioned patent application is hereby incorporated by reference herein and made a part of this specification.

### BACKGROUND

In recent years, with the development of data centers, artificial intelligence, supercomputers, and related technologies, increasingly powerful Application-Specific Integrated Circuits (ASICs) such as CPUs, GPUs, TPUs, NPUs, ML, AI accelerators, network switches, and servers have been widely deployed. These devices consume substantial electrical currents, often reaching several kiloamperes. To minimize transmission losses under high-current conditions, the power delivery approach has shifted from horizontal to vertical configuration, wherein the voltage regulator modules are positioned on the bottom surface of a smart card. Furthermore, as technology progresses, the supply voltages for processors have decreased significantly, such as below 1 V. The bottleneck for low-voltage, high-current voltage regulator modules (VRMs) is thermal management, as heat dissipation limitations restrict the ability to increase an output current of these modules.

The present application proposes a smart card assembly structure integrating a heat dissipation device.

### SUMMARY

In view of the above, one of the objectives of the application is to provide a A vertical power supply assembly, comprising a vertical heat dissipation device and a plurality of vertical power supply modules; wherein the vertical power supply modules are connected in parallel and configured to supply power to an XPU chip; wherein the vertical power supply modules are disposed at vertical corresponding positions relative to the XPU chip; wherein a gap exists between every two adjacent vertical power supply modules;

The vertical heat dissipation device comprises a heat conduction structure; and wherein the thermal conduction structure is disposed within the gap and/or on an outer side of the vertical power supply module.

Preferably, the thermal conduction structure comprises a bar-shaped thermal conduction column; an equivalent thermal conductivity of a long side of the thermal conduction column is greater than a thermal conductivity of copper; a cavity is disposed within the thermal conduction column, configured to accommodate cooling material.

Preferably, the number of cavities is at least two; the vertical heat dissipation device further comprises an inlet end and an outlet end; the cooling material is entered from the inlet end, passed through the at least two cavities respectively to perform heat exchange with the vertical power supply module, wherein the heat is carried out from the outlet end.

Preferably, the vertical heat dissipation device further comprises a horizontal heat dissipation substrate; the horizontal heat dissipation substrate is connected to the thermal conduction column and is thermally connected to a bottom surface of the vertical power supply module via a thermal conductive medium; a thickness of the horizontal heat dissipation substrate is greater than 0.5 mm; more than 50% of heat generated by the plurality of vertical power supply modules is transferred from the bottom surface of the vertical power supply module to the horizontal heat dissipation substrate, and then to the cooling material in the thermal conduction column; a height of the vertical power supply assembly is greater than a height of the vertical power supply module by at least 0.5 mm.

Preferably, the vertical power supply assembly further comprises a transverse thermal conduction device, the transverse thermal conduction device is disposed within the horizontal heat dissipation substrate or adhered to a surface of the horizontal heat dissipation substrate.

Preferably, a height difference between the vertical power supply assembly and the vertical power supply module is less than 0.5 mm, the thermal conduction column and a side surface of the vertical power supply module are thermally connected via a thermally conductive medium, wherein more than 50% of heat generated by the vertical power supply module is transferred to the thermal conduction column via the side surface.

Preferably, the vertical power supply module comprises switching devices, the switching devices are disposed on two opposite side surfaces of the vertical power supply module, the two opposite side surfaces are thermally connected to adjacent thermal conduction columns respectively.

Preferably, the vertical power supply module comprises switching devices and thermal conduction sheets, the switching devices are disposed on a bottom surface of the vertical power supply module, the thermal conduction sheets are disposed on two opposite side surfaces of the vertical power supply module, the two opposite side surfaces are thermally connected to adjacent thermal conduction columns respectively; the switching devices and the thermal conduction sheets are thermally connected.

Preferably, further comprising a hybrid substrate and a high-voltage power supply assembly; the hybrid substrate comprises a thermal conduction portion and a conductive portion; the thermal conduction portion is thermally connected to a bottom surface of the thermal conduction column; the conductive portion is disposed on a bottom surface of the vertical power supply module; the hybrid substrate is disposed between the high-voltage power supply assembly and the vertical power supply module; the high-voltage power supply assembly provides an input voltage to the vertical power supply module; the high-voltage power supply assembly, the hybrid substrate, and/or the vertical power supply module are fixed and electrically connected via welding or crimping.

Preferably, the transverse thermal conduction device is a heat pipe or a graphene sheet.

Preferably, the cooling material is a cooling liquid or a liquid-gas phase change material; the thermal conduction column is a water-cooled pipe or a heat pipe.

Preferably, the thermal conduction sheet is a copper sheet.

Preferably, the high-voltage power supply assembly is a high-voltage input bus or a high-voltage conversion device.

A smart card assembly integrating a heat sink, comprising a smart card mainboard, an XPU chip, an XPU substrate, a vertical power supply module, a main heat dissipation device, and a vertical heat dissipation device; wherein the XPU chip is disposed on a top surface of the XPU substrate, the XPU substrate is disposed on a top surface of the smart card mainboard; the vertical power supply module is disposed on a bottom surface of the smart card mainboard, wherein the vertical power supply module and the XPU chip are disposed in vertical correspondence, the XPU chip and the vertical power supply module are electrically connected via the XPU substrate and the smart card mainboard;

The main heat dissipation device is disposed on a top surface of the XPU chip and is thermally connected to the XPU chip; the vertical heat dissipation device is disposed on a bottom surface of the vertical power supply module; the vertical heat dissipation device comprises a thermal conduction structure, the thermal conduction structure is thermally connected to a side surface of the vertical power supply module.

Preferably, the thermal conduction structure is a bar-shaped thermal conduction column, an equivalent thermal conductivity of a long side of the thermal conduction column is greater than a thermal conductivity of copper; a cavity is disposed within the thermal conduction column for accommodating cooling material.

Preferably, the vertical heat dissipation device further comprises an inlet end and an outlet end; the cooling material is flowed in from the inlet end, passed through the thermal conduction column, and flowed out from the outlet end.

Preferably, the inlet end and the outlet end are in fluid communication with a fluid channel of the main heat dissipation device.

Preferably, the inlet end and the outlet end of the vertical heat dissipation device are disposed on opposite sides of the XPU chip, or disposed on the same side of the XPU chip.

Preferably, the vertical heat dissipation device covers a partial side surface and a partial bottom surface of the smart card mainboard.

Preferably, the smart card mainboard includes power conductive holes, the power conductive holes are penetrated through the top and bottom surfaces of the smart card mainboard and electrically connected to the XPU substrate and the vertical power supply module.

Compared with the prior art, the application has the following beneficial effects:
(1) The present application provides a structural configuration for a vertical power supply module that enables efficient heat dissipation of the vertical power supply modules through the vertical heat dissipation device in vertical power delivery scenarios;
(2) The present application provides a structural configuration for a smart card assembly where the vertical heat dissipation device and the main heat dissipation device are fluidically connected to rapidly and effectively dissipate heat from a bottom surface of the smart card assembly.

### DESCRIPTION OF DRAWINGS

FIG. 1 is a conventional structure of a smart card assembly.

FIG. 2 is a structure of an application scenario for a vertical power supply assembly.

FIG. 3A to FIG. 3E are embodiments of the vertical power supply module.

FIG. 4A to FIG. 4C are another embodiment of the vertical power supply module.

FIG. 5A is another embodiment of the vertical power supply module.

FIG. 5B is another structure of a smart card assembly structure.

### DETAILED DESCRIPTION

One of the cores of the present application is to provide a vertical power supply assembly and a smart card assembly.

Technical solutions in the embodiments of the present disclosure will be clearly and completely described below with reference to the accompanying drawings in the embodiments of the present disclosure. Apparently, the described embodiments are merely some rather than all of the embodiments of the present disclosure. All other embodiments obtained by a person of ordinary skill in the art based on the embodiments of the present disclosure without creative efforts shall fall within the protection scope of the present disclosure.

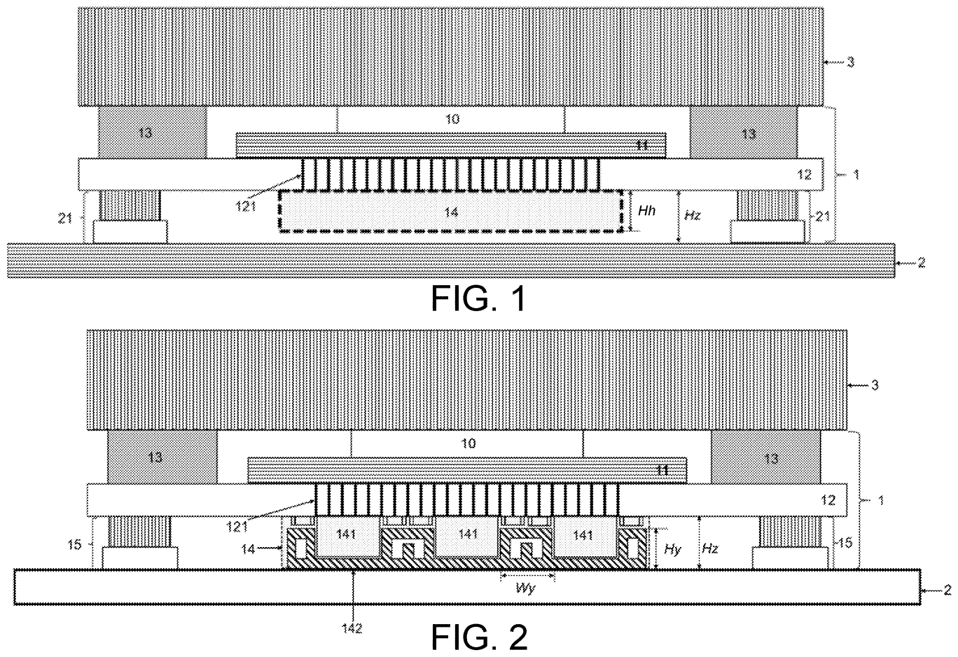

FIG. 1 is a conventional structure of a smart card assembly and application environment. As shown in FIG. 1, the smart card assembly 1 includes an XPU die 10, an XPU substrate 11, a smart card mainboard 12, a horizontal power supply module 13, and a vertical power supply assembly 14. The XPU die 10 is positioned on a top surface of the XPU substrate 11, a bottom surface of the XPU substrate 11 is adjoin a top surface of the smart card mainboard 12. The horizontal power supply module 13 is positioned on the top surface of the smart card mainboard 12 and around the XPU die 10. The vertical power supply assembly 14 is positioned on a bottom surface of the smart card mainboard 12 in a position that is vertically corresponding to the XPU die 10, the vertical correspondence refers to a projection of the XPU die 10 and vertical power supply assembly 14 on the top surface of the smart card mainboard 12 overlap at least partially, even to the extent of 50% overlap. The smart card mainboard 12 includes power conductive holes 121, the power conductive holes are penetrated through the top and bottom surfaces of the smart card mainboard and electrically connected to the XPU substrate 11 and the vertical power supply assembly 14. A top surface of the smart card assembly (including a top surface of the XPU die 10 and a top surface of the horizontal power supply module 13) is fixed and connected to a main heat dissipation device 3 for dissipating heat generated by the XPU die 10 and horizontal power supply module 13. The smart card assembly 1 is fixed and electrically connected to a substrate 2 via a connector 21, The substrate 2 is a system mainboard or other substrate or a physical barrier.

In conventional technology, the height (Hz) between the smart card mainboard 12 and the system mainboard is typically constrained. After installing the vertical power supply assembly 14, the available height for the vertical heat dissipation device (i.e., the heat dissipation device thermally connected to the vertical power supply assembly 14) is very small, such as only 1 mm; This limited height (Hz−Hh) makes it difficult to install an effective heat dissipation device for the vertical power supply assembly 14. The conventional solutions either sacrifice computational performance by using horizontal power supply modules, or increase the height of the connector 21 to increase the height (Hz−Hh) of the heat dissipation device. However, the increase in the height of the connector 21 reduces communication speed between the system mainboard and smart card assembly.

FIG. 2 illustrates a structure suitable for a vertical power supply assembly 14. The vertical power supply assembly 14 is positioned between the smart card mainboard 12 and substrate 2 and is vertically corresponding to the XPU die 10. The smart card mainboard 12 and substrate 2 are fixed and electrically connected via connector 21. The height between the smart card mainboard 12 and substrate 2 is Hz. The vertical power supply assembly 14 comprises multiple vertical power supply modules 141 and a vertical heat dissipation device 142. The vertical power supply modules 141 are positioned on the bottom surface of the smart card mainboard 12 and are directly fixed and electrically connected to the smart card mainboard 12. Output ends of the vertical power supply modules 141 are electrically parallel-connected to supply high current to the XPU die 10. Each vertical power supply module 141 has a height Hh. A plurality of vertical power supply modules 141 are spaced apart with gap of width Wy between adjacent modules, and the gap of width Wy at least 2 mm. In this embodiment, the gap is multiple. The vertical heat dissipation device 142 comprises a horizontal heat dissipation substrate and multiple thermal conduction columns. The horizontal heat dissipation substrate is positioned between the vertical power supply modules 141 and the substrate 2, and is adhered on a bottom surface of the vertical power supply modules 141 and a top surface of the substrate 2. The height of the horizontal heat dissipation substrate is optimally set at (Hz−Hh), while the overall height of the vertical heat dissipation device 142 is Hy. A portion of the thermal conduction columns is positioned within the gaps between adjacent vertical power supply modules 141, and another portion is positioned on the outside of the vertical power supply modules 141, such that both opposite side surfaces of each vertical power supply module 141 are adhered on the thermal conduction columns. The vertical heat dissipation device 142 dissipates heat for the multiple vertical power supply modules 141.

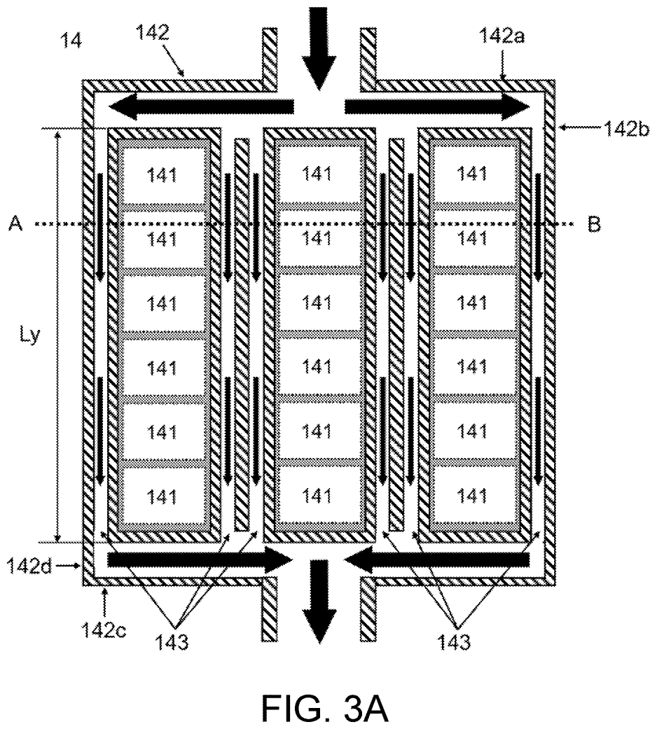

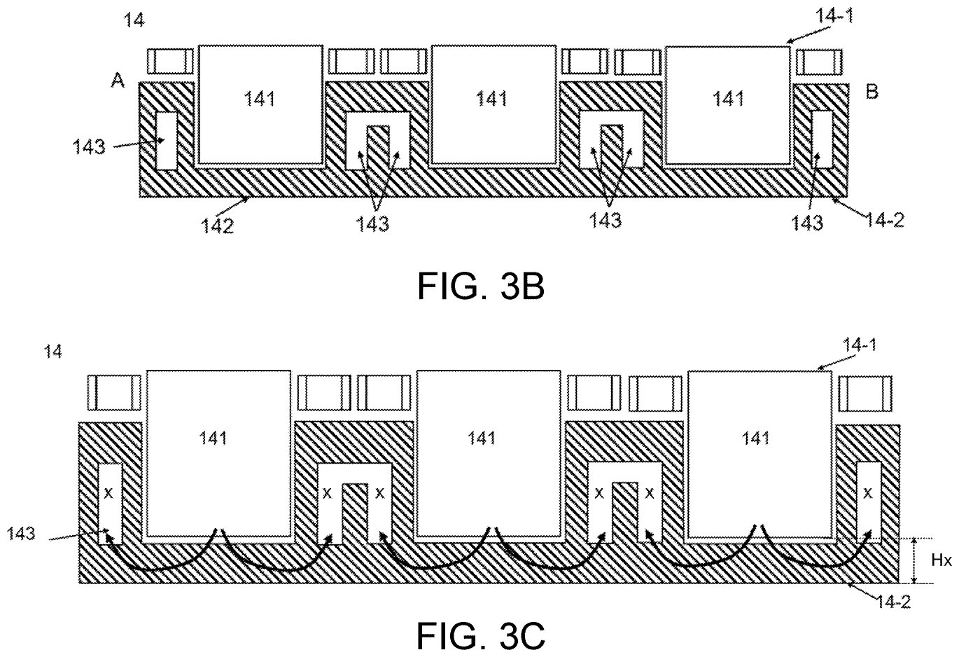

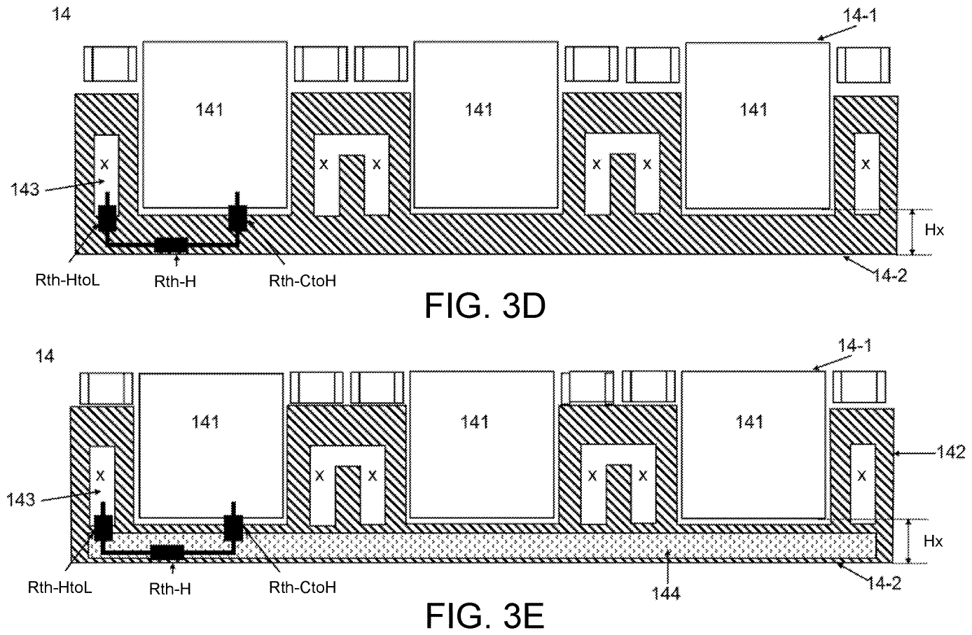

Simultaneously referring to the top view of the vertical power supply assembly 14 shown in FIG. 3A and the side cross-sectional view of the vertical power supply assembly 14 shown in FIG. 3B, where FIG. 3B illustrates the cross-section along line A-B of FIG. 3A. As shown in FIG. 3A, multiple vertical power supply modules 141 are arranged adjacent to each other in a raw, forming a vertical power supply array. A side surface of the vertical power supply array is thermally connected to the thermal conduction columns of the vertical heat dissipation device 142, while a bottom surface of the vertical power supply array is thermally connected to the horizontal heat dissipation substrate of the vertical heat dissipation device 142. Alternatively, both the side surface and the bottom surface of the vertical power supply array may thermally connect to the vertical heat dissipation device 142 via thermal conductive medium. In this embodiment, three vertical power supply arrays are used as an example. The number of the thermal conduction columns is four, and the thermal conduction columns are in bar-shaped and configured as liquid-cooled thermal conduction columns. An equivalent thermal conductivity of a long side of the thermal conduction columns is greater than a thermal conductivity of copper, the thermal conduction column is a water-cooled pipe or a heat pipe. Specifically, as shown in FIG. 3A, a first side 142a and a third side 142c opposite to each other, a second side 142b and a fourth side 142d opposite to each other. Each vertical power supply array and thermal conduction column are oriented such that their long sides are parallel to the second side 142b and the fourth side 142d. A length of the bar-shaped thermal conduction column is Ly. A cavity 143 is provide in each thermal conduction column. Each cavity 143 is in communication with positions adjacent to the first side 142a and the third side 142c. The cavity 143 is filled with a cooling material (such as a cooling liquid or a liquid-gas phase change material). An inlet of the cooling material is located at the first side 142a, while an outlet is located at the third side 142c. Low-temperature cooling material is flowed in from the inlet, dispersed through the multiple bar-shaped thermal conduction columns, exchanged heat with adjacent vertical power supply modules 141, and then the cooling material is flowed out from the outlet at the third side 142c to carry away the heat generated by the vertical power supply modules 141.

Further, as shown in FIG. 3C and FIG. 3D, a thickness of the horizontal heat dissipation substrate in the vertical heat dissipation device 142 is Hx, the thickness Hx is greater than 0.5 mm, with 1 mm being optimal. More than 50% of the total heat generated by the vertical power supply modules 141 is transferred from the bottom surface of the vertical power supply module to the horizontal heat dissipation substrate. An equivalent thermal resistance between the vertical power supply modules 141 and the horizontal heat dissipation substrate is Rth-CtoH. The heat is horizontally transferred along the horizontal heat dissipation substrate to adjacent bar-shaped thermal conduction column, an equivalent thermal resistance of the horizontal heat dissipation substrate is Rth-H; and then the heat is transferred to the cooling material via an equivalent thermal resistance Rth-HtoL and dissipated by the cooling material. In this embodiment, the vertical power supply device is positioned within a limited height Hz between the smart card mainboard 12 and the substrate 2, a pathway for power delivery to the XPU is reduced. The vertical heat dissipation device is positioned within the limited height Hz to provide a rapid and effective heat dissipation device pathway within for the vertical power supply device, thereby guaranteeing reliable operation of the vertical power supply device. Specifically, in scenarios with the height Hz (i.e., a height of the connector 15) greater than 5 mm, the height of the vertical power supply modules 141 is less than 5 mm. In scenarios with the height Hz of less than or equal to (including values approaching) 5 mm, the height of the vertical power supply modules 141 is less than 4 mm. In other words, the vertical power assembly 14 has the height exceeding the height of the vertical power supply modules 141 by at least 0.5 mm. The sufficient heat dissipation capability of the horizontal heat dissipation substrate is guaranteed.

In another embodiment, as shown in FIG. 3E, the horizontal heat dissipation substrate of the vertical heat dissipation device comprises a transverse thermal conduction device, such as a heat pipe or a graphene sheet. The transverse thermal conduction device is disposed within the horizontal heat dissipation substrate or adhered to a surface of the horizontal heat dissipation substrate. The equivalent thermal resistance Rth-H of the horizontal heat dissipation substrate is further reduced and the heat dissipation capability of the vertical heat dissipation device is further increased. In this embodiment, the transverse thermal conduction device is exemplified as being embedded within the horizontal heat dissipation substrate.

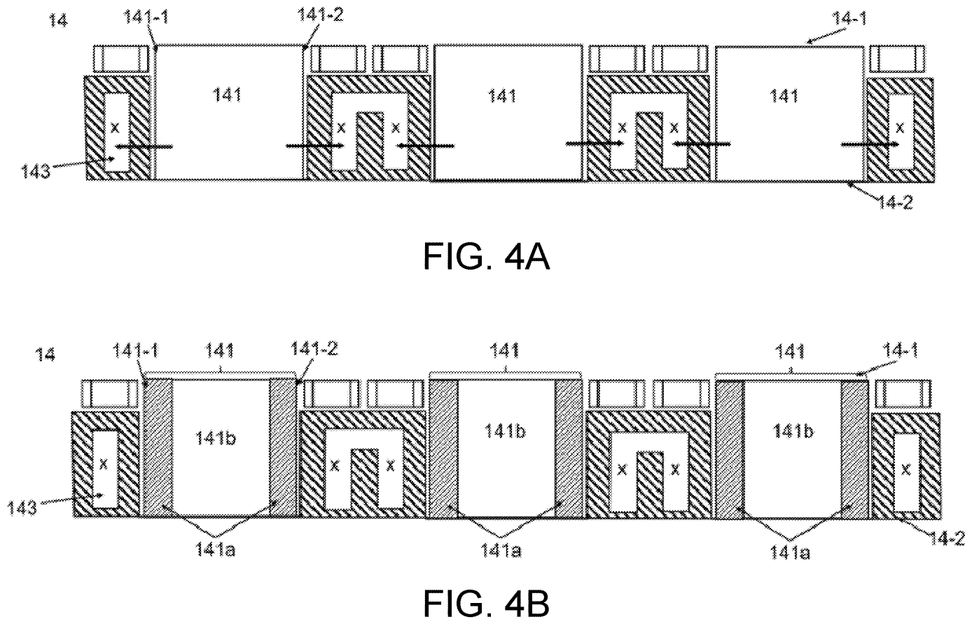

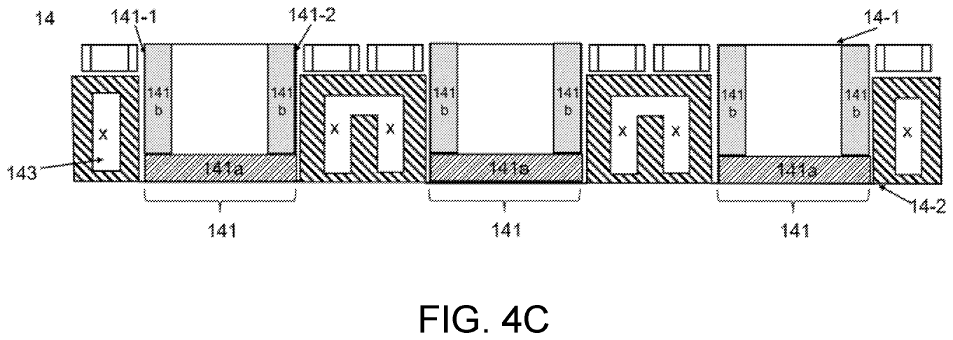

In another embodiment, as shown in FIG. 4A, a main heat source within the vertical power supply modules 141 is positioned on the side surfaces 141-1 and 141-2 of the vertical power supply modules that thermally connected to the vertical heat dissipation device 142. A thermal resistance between the vertical power supply modules 141 and the vertical heat dissipation device 142 is reduced by the thermal conductive medium. More than 50% of the heat generated by the vertical power supply modules 141 is transferred through the side surfaces 141-1 and 141-2 to the vertical heat dissipation device 142. In this embodiment, the horizontal heat dissipation substrate of the vertical heat dissipation device 142 may have a thickness less than or equal to 0.5 mm, with a thickness of 0 mm (i.e., no horizontal heat dissipation substrate) being optimal. Consequently, the height of vertical power supply assembly 14 equals the height of the vertical power supply module 141. In scenarios with the height Hz of less than or equal to (including values approaching) 5 mm, the height of the vertical power supply module 141 is less than 5 mm.

Further, this embodiment provides two structures of the vertical power supply module 141, as shown in FIG. 4B and FIG. 4C. As shown in FIG. 4B, one main heat source (i.e., switching device) of the power supply module is positioned on the side surfaces 141-1 and 141-2 of the vertical power supply module 141, enabling the switching device 141a is directly thermally connected to the vertical heat dissipation device 142. The thermal resistance between vertical power supply module 141 and the vertical heat dissipation device 142 is further reduced and the thermal dissipation capability is enhanced. Another structure of the vertical power supply module as shown in FIG. 4C, the switching device 141a is positioned on the bottom surface 141-2 of vertical power supply module 141; the side surfaces 141-1 and 141-2 of vertical power supply module include conductive columns 141b, which thermally connected with the switching device 141a. Outer surface of conductive columns 141b is thermally connected to the side surface of the vertical heat dissipation device 142. Thus, the heat generated by switching device 141a is transferred directly to the vertical heat dissipation device 142 via the conductive columns 141b. The conductive columns 141b may be a thermal conduction sheet or combing conductive properties to enable electrical connection between a top surface and a bottom surface of the vertical power supply module at corresponding potentials. The thermal conduction columns 141b are preferably made of a copper sheet, but is not limited thereto.

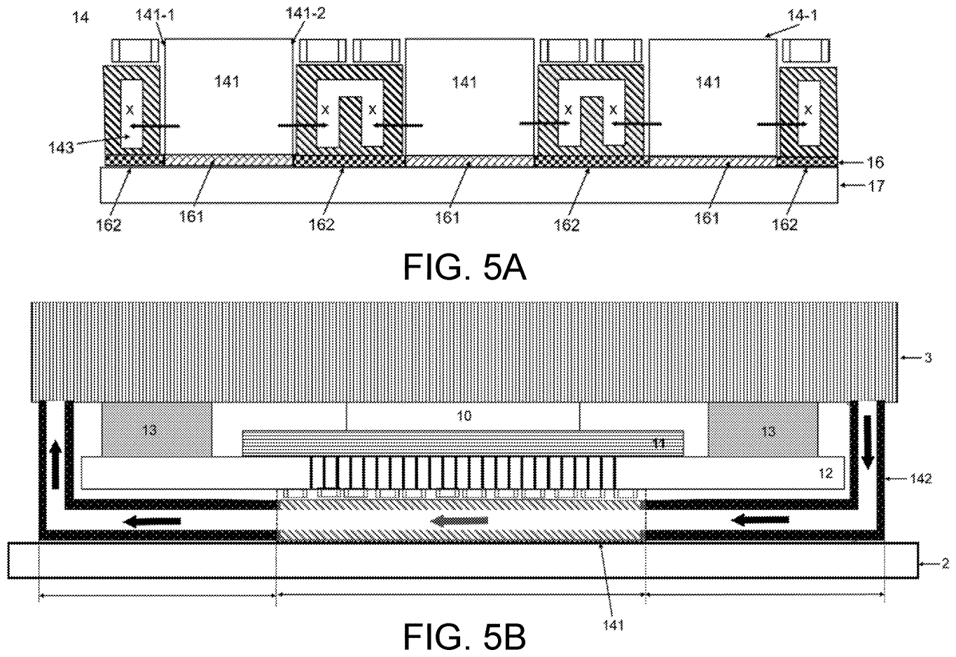

In another embodiment, as shown in FIG. 5A, more than 50% of the heat generated by the vertical power supply module 141 is transferred through the side surfaces 141-1 and 141-2 to the bar-shaped thermal conduction column. Therefore, the vertical power supply assembly 14 further includes a hybrid substrate 16 positioned adjacent to a bottom surface 14-2 of the vertical power supply assembly 14. The hybrid substrate 16 comprises a conductive portion 161 and a thermal conduction portion 162. The thermal conduction portion 62 is positioned on the bottom surface of the thermal conduction column, the conductive portion 161 is positioned on the bottom surface of the vertical power supply module 141. A high-voltage power supply assembly 17 is positioned on a bottom surface of the hybrid substrate 16, the high-voltage power supply assembly 17 can function as either a high-voltage input bus supplying input voltage to multiple vertical power supply modules, or a high-voltage conversion device that reduces a higher input voltage to the required the input voltage for vertical power supply modules 141 and supplies power to the multiple vertical power supply modules through the conductive portion 161; the input voltage is higher than 20V.

The high-voltage power supply assembly 17, the hybrid substrate 16, and/or the multiple vertical power supply modules 141 are fixed and electrically connected via welding or crimping. A top surface of the high-voltage power supply assembly 17 is thermally connected to the thermal conduction portion 162, enabling more than 50% of the heat generated by high-voltage power supply assembly 17 to be dissipated through thermal conduction column. This embodiment provides a more compact, producible power supply structure.

The vertical power supply assembly 14 further includes an output capacitor positioned on the top surface of the thermal conduction column, thermally connected via the thermally conductive medium to dissipate heat generated by the capacitor.

FIG. 5B illustrates a smart card assembly integrating a heat sink. The smart card assembly comprises the main heat dissipation device 3, the vertical heat dissipation device 142, the XPU die 10, the XPU substrate 11, the smart card mainboard 12, and the vertical power supply module 141. The XPU die 10 is positioned on the top surface of the XPU substrate 11. The bottom surface of the XPU substrate 11 is adjoin the top surface of the smart card mainboard 12. The vertical power supply module 141 is positioned on the bottom surface of the smart card mainboard 12 and is vertically corresponding to the XPU die 10. The smart card mainboard 12 includes power conductive holes 121, the power conductive holes 121 are penetrated through the top and bottom surfaces of the smart card mainboard and electrically connected the XPU substrate 11 and the vertical power supply assembly 14. The smart card assembly further includes a horizontal power supply module 13. The horizontal power supply module 13 is positioned on the top surface of the smart card mainboard 12 surrounding the XPU die 10. The main heat dissipation device 3 is positioned on the top surface of the XPU die 10 to dissipate heat generated by the XPU die 10. The vertical heat dissipation device 142 covers portions of the side surfaces and portion of the bottom surface of the smart card mainboard 12. The vertical heat dissipation device 142 includes an inlet end, the thermal conduction column, and an outlet end. The inlet end and outlet end are in fluid communication with a fluid channel of the main heat dissipation device 3. The thermal conduction column is positioned adjacent to the side surfaces of the vertical power supply module 141 and the bottom surface of the smart card mainboard 12 and transfers heat to the main heat dissipation device 3 via the cooling material in a horizontal channel. FIG. 5B illustrates a cross-section along the length of the thermal conduction column. The inlet end and the outlet end of the vertical heat dissipation device 142 may be positioned on opposite sides or the same side of the XPU chip 10. The XPU chip 10 may be a bare chip or a packaged chip. By connecting the vertical heat dissipation device 142 to the main heat dissipation device 3, this embodiment enables faster and more effective dissipation of heat from the bottom surface of smart card mainboard 12, reducing the operating temperature of the vertical power supply modules 141 and ensuring reliable operation.

The vertical power supply assembly according to the embodiment can be a part of the electronic device, and can meet the technical features and advantages disclosed by the application.

The “equal” or “same” or “equal to” disclosed by the application needs to consider the parameter distribution of engineering, and the error distribution is within +/−30%; and the included angle between the two line segments or the two straight lines is less than or equal to 45 degrees; the included angle between the two line segments or the two straight lines is within the range of [60, 120]; and the definition of the phase error phase also needs to consider the parameter distribution of the engineering, and the error distribution of the phase error degree is within +/−30%.

The embodiments in the specification are described in a progressive manner, each embodiment focuses on the difference from other embodiments, and the same similar parts between the embodiments can be referred to each other.

The above description of the disclosed embodiments enables a person skilled in the art to implement or use the present application. Various modifications to these embodiments will be readily apparent to those skilled in the art, and the generic principles defined herein may be implemented in other embodiments without departing from the spirit or scope of the application. Thus, the present application will not be limited to the embodiments shown herein but is to be accorded the widest scope consistent with the principles and novel features disclosed herein.

What is claimed is:

1. A vertical power supply assembly, comprising a vertical heat dissipation device and a plurality of vertical power supply modules, wherein the vertical power supply modules are connected in parallel and configured to supply power to an XPU chip; wherein the vertical power supply modules are disposed at vertical corresponding positions relative to the XPU chip; wherein a gap exists between every two adjacent vertical power supply modules,
wherein the vertical heat dissipation device comprises a heat conduction structure; and wherein the thermal conduction structure is disposed within the gap and/or on an outer side of the vertical power supply module.

2. The vertical power supply assembly of claim 1, wherein the thermal conduction structure comprises a bar-shaped thermal conduction column; an equivalent thermal conductivity of a long side of the thermal conduction column is greater than a thermal conductivity of copper; a cavity is disposed within the thermal conduction column, configured to accommodate cooling material.

3. The vertical power supply assembly of claim 2, wherein a number of cavities is at least two; the vertical heat dissipation device further comprises an inlet end and an outlet end; the cooling material is entered from the inlet end, passed through the at least two cavities respectively to perform heat exchange with the vertical power supply module, wherein the heat is carried out from the outlet end.

4. The vertical power supply assembly of claim 3, wherein the vertical heat dissipation device further comprises a horizontal heat dissipation substrate; the horizontal heat dissipation substrate is connected to the thermal conduction column and is thermally connected to a bottom surface of the vertical power supply module via a thermal conductive medium; a thickness of the horizontal heat dissipation substrate is greater than 0.5 mm; more than 50% of heat generated by the plurality of vertical power supply modules is transferred from the bottom surface of the vertical power supply module to the horizontal heat dissipation substrate, and then to the cooling material in the thermal conduction column; a height of the vertical power supply assembly is greater than a height of the vertical power supply module by at least 0.5 mm.

5. The vertical power supply assembly of claim 4, wherein the vertical power supply assembly further comprises a transverse thermal conduction device, the transverse thermal conduction device is disposed within the horizontal heat dissipation substrate or adhered to a surface of the horizontal heat dissipation substrate.

6. The vertical power supply assembly of claim 3, wherein a height difference between the vertical power supply assembly and the vertical power supply module is less than 0.5 mm, the thermal conduction column and a side surface of the vertical power supply module are thermally connected via a thermally conductive medium, wherein more than 50% of heat generated by the vertical power supply module is transferred to the thermal conduction column via the side surface.

7. The vertical power supply assembly of claim 6, wherein the vertical power supply module comprises switching devices, the switching devices are disposed on two opposite side surfaces of the vertical power supply module, the two opposite side surfaces are thermally connected to adjacent thermal conduction columns respectively.

8. The vertical power supply assembly of claim 6, wherein the vertical power supply module comprises switching devices and thermal conduction sheets, the switching devices are disposed on a bottom surface of the vertical power supply module, the thermal conduction sheets are disposed on two opposite side surfaces of the vertical power supply module, the two opposite side surfaces are thermally connected to adjacent thermal conduction columns respectively; the switching devices and the thermal conduction sheets are thermally connected.

9. The vertical power supply assembly of claim 3, further comprising a hybrid substrate and a high-voltage power supply assembly; the hybrid substrate comprises a thermal conduction portion and a conductive portion; the thermal conduction portion is thermally connected to a bottom surface of the thermal conduction column; the conductive portion is disposed on a bottom surface of the vertical power supply module; the hybrid substrate is disposed between the high-voltage power supply assembly and the vertical power supply module; the high-voltage power supply assembly provides an input voltage to the vertical power supply module; the high-voltage power supply assembly, the hybrid substrate, and/or the vertical power supply module are fixed and electrically connected via welding or crimping.

10. The vertical power supply assembly of claim 5, wherein the transverse thermal conduction device is a heat pipe or a graphene sheet.

11. The vertical power supply assembly of claim 1, wherein the cooling material is a cooling liquid or a liquid-gas phase change material; the thermal conduction column is a water-cooled pipe or a heat pipe.

12. The vertical power supply assembly of claim 8, wherein the thermal conduction sheet is a copper sheet.

13. The vertical power supply assembly of claim 9, wherein the high-voltage power supply assembly is a high-voltage input bus or a high-voltage conversion device.

14. A smart card assembly integrating a heat sink, comprising a smart card mainboard, an XPU chip, an XPU substrate, a vertical power supply module, a main heat dissipation device, and a vertical heat dissipation device, wherein the XPU chip is disposed on a top surface of the XPU substrate, the XPU substrate is disposed on a top surface of the smart card mainboard; the vertical power supply module is disposed on a bottom surface of the smart card mainboard, wherein the vertical power supply module and the XPU chip are disposed in vertical correspondence, the XPU chip and the vertical power supply module are electrically connected via the XPU substrate and the smart card mainboard;
wherein the main heat dissipation device is disposed on a top surface of the XPU chip and is thermally connected to the XPU chip; the vertical heat dissipation device is disposed on a bottom surface of the vertical power supply module; the vertical heat dissipation device comprises a thermal conduction structure, the thermal conduction structure is thermally connected to a side surface of the vertical power supply module.

15. The smart card assembly of claim 14, wherein the thermal conduction structure is a bar-shaped thermal conduction column, an equivalent thermal conductivity of a long side of the thermal conduction column is greater than a thermal conductivity of copper; a cavity is disposed within the thermal conduction column for accommodating cooling material.

16. The smart card assembly of claim 15, wherein the vertical heat dissipation device further comprises an inlet end and an outlet end; the cooling material is flowed in from the inlet end, passed through the thermal conduction column, and flowed out from the outlet end.

17. The smart card assembly of claim 14, wherein the inlet end and the outlet end are in fluid communication with a fluid channel of the main heat dissipation device.

18. The smart card assembly of claim 16, wherein the inlet end and the outlet end of the vertical heat dissipation device are disposed on opposite sides of the XPU chip, or disposed on the same side of the XPU chip.

19. The smart card assembly of claim 14, wherein the vertical heat dissipation device covers a partial side surface and a partial bottom surface of the smart card mainboard.

20. The smart card assembly of claim 14, wherein the smart card mainboard includes power conductive holes, the power conductive holes are penetrated through the top and bottom surfaces of the smart card mainboard and electrically connected to the XPU substrate and the vertical power supply module.
